(19) United States
(12) Patent Application Publication
(10) Pub. No.: US 2007/0104237 A1
(43) Pub. Date: May 10, 2007

(54) Semiconductor laser apparatus and semiconductor laser device

(75) Inventor: Mitsuhiro Matsumoto, Kashihara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/594,266

(22) Filed: Nov. 7, 2006

(30) Foreign Application Priority Data
Nov. 7, 2005 (JP) 2005-322678

(51) Int. Cl. H01S 5/00

(52) U.S. Cl. 372/43.01

(57) ABSTRACT

In an outermost surface of a semiconductor laser device to which a solder layer is applied, an incomplete adherent layer is formed which is incompletely adhered to the solder layer, extends in a width direction perpendicular to a longitudinal direction of a light-emitting region and a stacking direction of the semiconductor laser device, the solder layer and a mount, outwardly to either side by a predetermined second distance from a virtual plane which passes through a center of the light-emitting region and is perpendicular to the width direction and which incomplete adherent layer has a longitudinal length shorter than that of the light-emitting region. Further, in an area of the outermost surface excluding the incomplete adherent layer is formed a complete adherent layer.

### CROSS-REFERENCE TO RELATED APPLICATION

This application claims priority to Japanese Patent Application No. JP 2005-322678, which was filed on Nov. 7, 2005, the contents of which, are incorporated herein by reference, in their entirety.

### BACKGROUND OF THE INVENTION

1. Field of the Invention

The present invention relates to a semiconductor laser apparatus and a semiconductor laser device.

2. Description of the Related Art

In a semiconductor laser apparatus formed by mounting a semiconductor laser chip on a heat sink, a difference in thermal expansion coefficient between the semiconductor laser device and the heat sink generates stress, causing a problem that an internal stress is generated in the semiconductor laser chip, that is, a problem that a semiconductor layer constituting the semiconductor laser chip suffers from strain.

In view of such a problem, there has been provided a semiconductor laser apparatus of related art, in which the internal stress of the semiconductor laser chip is reduced by virtue of a shape of electrode of the semiconductor laser chip.

The above-described semiconductor laser device is disclosed on Japanese Examined Patent Publication JP-B2 3461632. FIG. 11 is a sectional view of a semiconductor laser apparatus 1 of related art as described above. FIG. 12 is a plan view of a semiconductor laser chip 2 in the semiconductor laser apparatus 1 when seen from a lower electrode 3 side. The semiconductor laser apparatus 1 has a semiconductor laser chip 2, a solder layer 4, and a heat sink 5. The semiconductor laser chip 2 is mounted on the heat sink 5 via the solder layer 4.

The heat sink 5 has one surface in a thickness direction thereof on which a heat sink upper electrode 6 is formed, and the other surface in a thickness direction thereof on which a heat sink lower electrode 7 is formed. To the heat sink upper electrode 6 is applied the solder layer 4 on which the semiconductor laser chip 2 is stacked so that the lower electrode 3 faces the solder layer 4.

The semiconductor laser chip 2 is constituted in a manner that an active layer 13 and a cap layer 15 are stacked in this order on the other surface in a thickness direction of a substrate 11, and an ohmic electrode layer 16 and a non-alloying electrode layer 17 are stacked in this order on the cap layer 15, while a semiconductor laser chip upper electrode 18 is formed on one surface in a thickness direction of the substrate 11. On a part of the non-alloying electrode layer 17 is stacked an alloying electrode layer 19 which forms the lower electrode 3 of the semiconductor laser chip 2 together with the non-alloying electrode layer 17.

In a surface of the lower electrode 3 of the semiconductor laser chip 2 facing the semiconductor layer 4 stacked on the heat sink upper electrode 6 of the heat sink 5 is formed a region 21 having a predetermined width ranging from a surface portion located right under a central line in a longitudinal direction of a light-emitting region 8 of the semiconductor laser chip 2 to both sides of the central line. The region 21 is formed in the non-alloying electrode layer 17 which is not alloyed with the solder layer. A surface of the lower electrode 3 excluding the region 21 is alloyed with the solder layer 4 and thereby adhered to the solder layer 4. The region 21 is formed from one end to the other end of the longitudinal direction of the light-emitting region 8, that is, between one end and the other end of a longitudinal direction of the semiconductor laser chip 2.

Upon heat-sealing the semiconductor laser chip 2 and the heat sink 5 by use of a solder material, the alloying electrode layer 19 shown in FIG. 11 is alloyed with a solder material applied to the heat sink 5 and thereby adhered solidly to the solder layer 4 while the non-alloying electrode layer 17 shown in FIG. 11 is not alloyed with the solder material applied to the heat sink 5 and therefore not adhered solidly to the solder layer 4. Accordingly, the internal stress in the non-alloying electrode layer 17 is lower than that in the alloying electrode layer 19. Since the light-emitting region 8 is formed in a non-alloying region where the non-alloying electrode layer 17 contacts the solder layer 4, the internal stress on the light-emitting region 8 can be reduced, with the result that reliability of the semiconductor laser apparatus 1 can be enhanced.

In the semiconductor laser apparatus 1 of related art, a part of the lower electrode 3 of the semiconductor laser chip 2, which is stacked on the light-emitting region 8, is provided with the non-alloying electrode layer 17 to thereby decrease the strength of bonding between the lower electrode 3 and the solder layer 4 applied to the heat sink 5. This helps prevent the semiconductor laser chip 2 from having the internal stress generated therein. However, the weak bonding between the non-alloying electrode 17 and the solder layer 4 leads a problem such that heat generated by the light-emitting region 8 is hard to be conducted from the non-alloying electrode layer 17 to the solder layer 4, resulting in deterioration in efficiency of dissipating heat toward the heat sink 5 and an increase in operating current at a high temperature, which leads deterioration in reliability at a high temperature.

### SUMMARY OF THE INVENTION

An object of the invention is to provide a semiconductor laser device in which reduced stress is generated under the condition that it is mounted on a mount and an efficiency of dissipating heat toward the mount is enhanced to prevent a rise of operating current at high temperature, and to a semiconductor laser apparatus having the laser device mounted on a mount.

The invention provides a semiconductor laser apparatus comprising a semiconductor laser device having a stripe-shaped light emitting region, and a mount to which the semiconductor laser device is adhered via a solder layer,

wherein an outermost surface of the semiconductor laser device to which the solder layer is applied is electrically conductive and the outermost surface has an incomplete adherent region which is incompletely adhered to the solder layer, extends in a width direction perpendicular to a longitudinal direction of the light-emitting region and a stacking direction of the semiconductor laser device, the solder layer and the mount, outwardly to either side by a predetermined distance from a virtual plane which passes through a center of the light-emitting region and is perpendicular to the width direction, and which incomplete adherent region has a longitudinal length shorter than that of the light-emitting region, and the outermost surface has a complete adherent region which is adhered to the solder layer and extends over an area of the outermost surface excluding the incomplete adherent region.

According to the invention, the incomplete adherent layer is formed in the outermost surface of a semiconductor laser device to which outermost surface the solder layer is applied. The incomplete adherent region extends outwardly to either side by a predetermined distance from a virtual plane which passes through a center of the light-emitting region and is perpendicular to the width direction as viewed in a width direction perpendicular to the longitudinal direction of the light-emitting region and the stacking direction of the semiconductor laser device and the solder layer onto the mount. In the incomplete adherent region, the outermost surface is not or incompletely adhered to the solder layer. Accordingly, it is possible to reduce the stress imparted to the light-emitting region, which is caused by differences in thermal expansion coefficient among the semiconductor laser apparatus, the solder layer, and the mount during operation. As a result, the degree of strain in the light-emitting region can be. Moreover, when viewed in the longitudinal direction of the light-emitting region, a length of the incomplete adherent region is shorter than a length of the light-emitting region, with the result that a part of the above-stated area is completely adhered to the solder layer at a part of the outermost surface stacked over the light-emitting region. This facilitates conduction of heat generated by the light-emitting region also in the above-stated area adjacent to the light-emitting region, resulting in enhancement in efficiency of dissipating heat toward the mount. Consequently, the operating current at a high temperature is prevented from increasing so that the reliability at a high temperature can be enhanced.

Further, the complete adherent region formed in an area of the outermost surface excluding the incomplete adherent region allows a solid mechanical coupling between the semiconductor laser device and the mount.

Further, in the invention, it is preferable that the incomplete adherent region is formed at a light-emitting end of the semiconductor laser device.

According to the invention, in a part of the light-emitting region where the complete adherent layer is stacked on the outermost surface, light passing through the light-emitting region is influenced by refractive index fluctuation caused by internal stress, that is, strain due to stress, whereas in a part of the light-emitting region where the incomplete adherent layer is stacked on the outermost surface, light passing through the light-emitting region is less easily influenced by the refractive index fluctuation by virtue of a small amount of the internal stress, allowing reduction of the distortions arising in the radiation pattern. The light passing through the light-emitting region thus passes through a part which is susceptible to the refractive index fluctuation caused by internal stress, and a part which is less easily influenced by the refractive index fluctuation. Owing to the incomplete adherent region formed at a light-emitting end, the light-emitting end is less easily influenced by the refractive index fluctuation and therefore, it is possible to prevent the distortions from arising in the radiation pattern of the laser light being emitted.

Further, in the invention, it is preferable that a ratio of the longitudinal length of the incomplete adherent region to that of the light-emitting region is 20% or more and 80% or less.

According to the invention, if a ratio of the longitudinal length of the incomplete adherent region to that of the light-emitting region is less than 20%, an increase of internal crystal defects caused by the strain of the light-emitting region drastically deteriorates the service life of the semiconductor laser apparatus, resulting in a short service life. If a ratio of the longitudinal length of the incomplete adherent region to that of the light-emitting region exceeds 80%, the efficiency of dissipating heat from the complete adherent region is low, resulting in a drastic increase of the operating current at a high temperature. According to the invention, by adjusting the ratio of the longitudinal length of the incomplete adherent region to that of the light-emitting region to be 20% or more and 80% or less, it is possible to provide a semiconductor laser apparatus having enhanced service life and operating reliability at a high temperature, in which a service life of a semiconductor laser device can be prevented from decreasing and an operating current at a high temperature can be prevented from increasing.

Further, in the invention, it is preferable that a part included in the incomplete adherent region of the outermost surface is made of one or more substances selected from a group consisting of Mo, Pt, and Ti, and

wherein a part included in the complete adherent region of the outermost surface is made of alloy of a material containing Au and a solder material made of AuSn, and

wherein the solder layer is made of a solder material made of AuSn.

According to the invention, a part included in the incomplete adherent region of the outermost surface is made of one or more substances selected from a group consisting of Mo, Pt, and Ti, and a part included in the complete adherent region of the outermost surface is made of alloy of a material containing Au and a solder material made of AuSn, and the solder layer is made of a solder material made of AuSn, with the result that a semiconductor laser apparatus achieving the above-described effects can be easily realized.

Further, in the invention, it is preferable that in the incomplete adherent region, a-void is formed between the outermost surface and the solder layer.

According to the invention, in the incomplete adherent region, a void formed between the outermost surface and the solder layer allows further reduction of the internal stress imposed on the light-emitting region of the semiconductor laser device, with the result that the service life of the semiconductor laser device can be enhanced furthermore.

Further, in the invention, it is preferable that a part included in the incomplete adherent region of the outermost surface is made of Mo, and

wherein a part included in the complete adherent region of the outermost surface is made of alloy of a material containing Au and a solder material made of AuSn, and

wherein the solder layer is made of a solder material made of AuSn.

According to the invention, a part included in the incomplete adherent region of the outermost surface is made of Mo, and a part included in the complete adherent region of the outermost surface is made of alloy of a material containing Au and a solder material made of AuSn, and the solder layer is made of a solder material made of AuSn. Since Mo is not alloyed with AuSn, the outermost surface made of Mo does not make intimate contact with the solder layer made of AuSn, with the result that the above-described void can be easily attained. Moreover, the part included in the complete adherent region is made of alloy of a material containing Au and a solder material made of AuSn and therefore, solidly adhered to the solder layer made of AuSn.

Further, in the invention, it is preferable that the incomplete adherent region and the complete adherent region are formed alternately along the longitudinal direction of the semiconductor laser device in an area ranging outward by the predetermined distance on either side from the virtual plane which passes through the center in the width direction of the light-emitting region and which is perpendicular to the width direction.

According to the invention, the incomplete adherent region and the complete adherent region are formed alternately along a longitudinal direction of the semiconductor laser device in an area ranging outward by a predetermined distance on either side from a virtual plane which passes through a center in the width direction of the light-emitting region and which is perpendicular to the width direction, with the result that, in the area, the internal stress of the semiconductor laser device can be dispersed in the longitudinal direction of the light-emitting region and furthermore, heat transmission paths of high heat conduction can be dispersed in the longitudinal direction of the light-emitting region. Accordingly, the internal stress imparted to the light-emitting region is equalized as much as possible when viewed in the longitudinal direction so that the distortions arising in the radiation pattern can be reduced. Further, the heat conduction from the light-emitting region to the mount is equalized as much as possible when viewed in the longitudinal direction so that a temperature of the light-emitting region can be made as uniform as possible. As a result, it is possible to further prevent the operating current at a high temperature from increasing.

Further, the invention provides a semiconductor laser device that is adhered to a mount via a solder layer, comprising:

a stripe-shaped light-emitting region; and

an outermost surface which is electrically conductive and to which the solder layer is applied, the outermost surface having an incomplete adherent region and a complete adherent region,

wherein the incomplete adherent region is incompletely adhered to the solder layer, extends in a width direction perpendicular to a longitudinal direction of the light-emitting region and a stacking direction of the semiconductor laser device, the solder layer and the mount, outwardly to either side by a predetermined distance from a virtual plane which passes through a center of the light-emitting region and is perpendicular to the width direction, and the incomplete adherent region has a longitudinal length shorter than that of the light-emitting region, and the complete adherent region is adhered to the solder layer and extends over an area of the outermost surface excluding the incomplete adherent region.

According to the invention, the incomplete adherent layer is not or incompletely adhered to the solder layer, and it is therefore possible to reduce the stress which is imparted to the semiconductor laser device by thermal expansion and thermal contraction of a solder material upon heat-sealing the semiconductor laser device onto the heat sink by soldering, with the result that the degree of strain in the light-emitting region can be reduced. Moreover, during operation of the semiconductor laser device already mounted on the mount, it is possible to reduce the stress caused by differences in thermal expansion coefficient among the semiconductor laser apparatus, the solder layer, and the mount so that the degree of strain in the light-emitting region can be reduced. Furthermore, when viewed in the longitudinal direction of the light-emitting region, a length of the incomplete adherent layer is shorter than a length of the light-emitting region, with the result that a part of the above-stated area of the outermost surface stacked on the light-emitting region is completely adhered to the solder layer, thus effecting easier conduction of heat generated by the light-emitting region to the mount through the solder layer. By so doing, the efficiency of dissipating heat to the mount can be enhanced so that the operating current at a high temperature is prevented from increasing, allowing enhancement in reliability at a high temperature.

Further, the complete adherent region formed in an area of the outermost surface excluding the incomplete adherent region allows a solid mechanical coupling between the semiconductor laser device and the mount.

Further, in the outermost surface region of the semiconductor laser device to which the solder layer is applied are formed the incomplete adherent layer and the complete adherent layer. That is, the semiconductor laser device is mounted onto the mount via the solder layer applied to the incomplete adherent layer and the complete adherent layer. In this case, the solder layer can be applied to the entire stacking surface of the outermost surface without the necessity of being subjected to processing in some way, thus facilitating the mounting of the semiconductor laser device onto the mount.

### BRIEF DESCRIPTION OF THE DRAWINGS

Other and further objects, features, and advantages of the invention will be more explicit from the following detailed description taken with reference to the drawings wherein:

FIG. 1 is a plan view of a semiconductor laser device provided in a semiconductor laser apparatus according to one embodiment of the invention when seen from a side to be mounted onto a mount;

FIG. 2 is a sectional view of the semiconductor laser device taken along the line II-II of FIG. 1;

FIG. 3 is a sectional view of the semiconductor laser device adhered to a mount via a solder layer when seen from the line II-II of the semiconductor laser apparatus;

FIG. 4 is a sectional view of the semiconductor laser device adhered to the mount via the solder layer when seen from the line III-III of the semiconductor laser apparatus;

FIG. 5 is a graph showing the relationship between a ratio of a length of an incomplete adherent region to a length of a light-emitting region when viewed in a longitudinal direction X, and a service life of the semiconductor laser apparatus;

FIG. 6 is a graph showing the relationship between the ratio of the length of the incomplete adherent region to that of the light-emitting region when viewed in the longitudinal direction X, and an operating current of the semiconductor laser apparatus;

FIG. 7 is a graph showing a radiation pattern of emitted light of the semiconductor laser apparatus according to the embodiment;

FIG. 8 is a graph showing a radiation pattern of emitted light of a semiconductor laser apparatus of a comparative example;

FIG. 9 is a sectional view showing a semiconductor laser apparatus according to another embodiment of the invention;

FIG. 10 is a plan view of a semiconductor laser device provided in a semiconductor laser apparatus according to still another embodiment of the invention when seen from a side to be mounted onto the mount;

FIG. 11 is a sectional view of a semiconductor laser apparatus of the related art; and

FIG. 12 is a plan view of a semiconductor laser chip in the semiconductor laser apparatus when seen from a lower electrode side.

### DETAILED DESCRIPTION

Now referring to the drawings, preferred embodiments of the invention are described below.

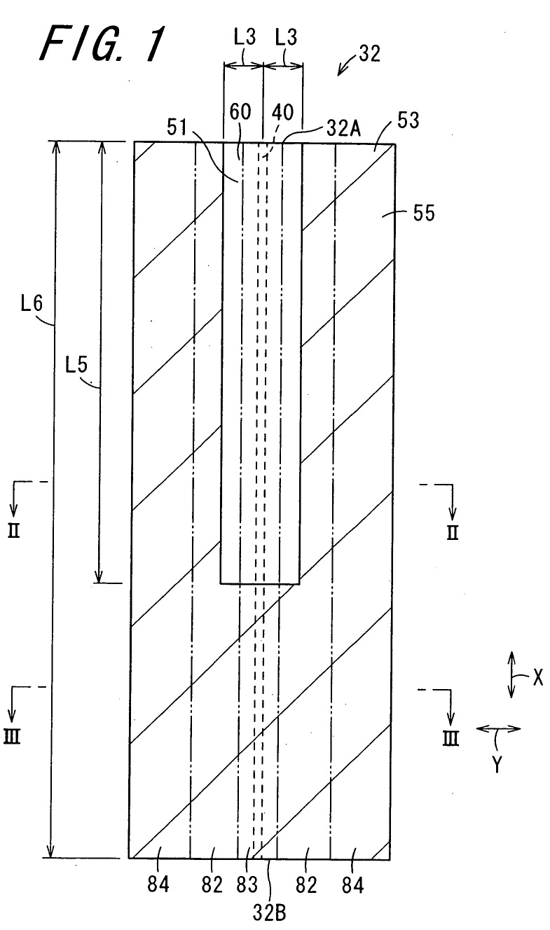

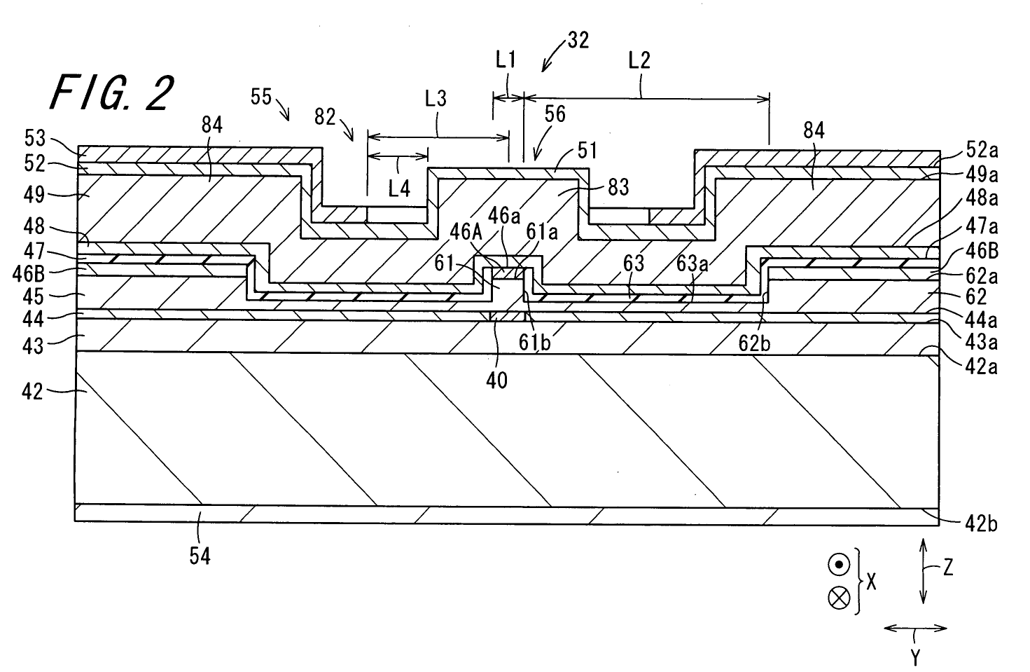

FIG. 1 is a plan view of a semiconductor laser device 32 provided in a semiconductor laser apparatus 31 according to one embodiment of the invention when seen from a side to be mounted onto a mount 72. FIG. 2 is a sectional view of the semiconductor laser device 32 taken along the line II-II of FIG. 1. Note that a complete adherent layer 53 shown in FIG. 1 is diagonally shaded for the sake of simplifying an understanding of the illustration.

The semiconductor laser device 32 is built as a semiconductor laser chip. In the present embodiment, the semiconductor laser device 32 has a ridge structure. The semiconductor laser device 32 is composed of a semiconductor substrate 42, a first clad layer 43, an active layer 44, a second clad layer 45, a cap layer 46A, a terrace portion carrying layer 46B, an insulating layer 47, an ohmic electrode layer 48, a plate electrode layer 49, a metal layer 52 including an incomplete adherent layer 51, a complete adherent layer 53, and a back-side electrode layer 54 serving as a second electrode. The semiconductor laser device 32 is formed into a schematic rectangular parallelepiped shape.

The semiconductor substrate 42 can stack thereon semiconductor layers made of a compound semiconductor. In the present embodiment, the semiconductor substrate 42 is made of n-type gallium arsenide (GaAs). The semiconductor substrate 42 has a quadrilateral cross-sectional profile when viewed in a thickness direction Z. The thickness of the semiconductor substrate 42 is adjusted to fall in a range of from 50 μm to 130 μm, for example.

The first clad layer 43 is formed on one surface 42a in a thickness direction Z of the semiconductor substrate 42 so as to be stacked over the entire one surface 42a with use of n-type (AlₓGa₁₋ₓ)In_{1-Y}P, wherein the following conditions have to be satisfied: 0<X<1 and 0<Y<1. In the present embodiment, the value of X is set at 0.7, and the value of Y is set at 0.5. That is, the first clad layer 43 is made of n-type (Al_{0.7}Ga_{0.3})_{0.5}In_{0.5}P. The thickness of the first clad layer 43 is set at 2.0 μm, for example.

The active layer 44 is formed on one surface 43a in a thickness direction Z of the first clad layer 43 so as to be stacked on the entire one surface 43a. The active layer 44 takes on a quantum well structure composed of: a first guide layer stacked on Z direction-wise one surface 43a of the first clad layer 43; a first well layer stacked on Z direction-wise one surface of the first guide layer; a first barrier layer stacked on Z direction-wise one surface of the first well layer; a second well layer stacked on Z direction-wise one surface of the first barrier layer; a second barrier layer stacked on Z direction-wise one surface of the second well layer; a third well layer stacked on Z direction-wise one surface of the second barrier layer; and a second guide layer stacked on Z direction-wise one surface of the third well layer. Each of the first, second, and third well layers is made of In_{0.5}Ga_{0.5}P, the thickness of which is set at 60 Å, for example. Each of the first and second barrier layers is made of (Al_{0.5}Ga_{0.5})_{0.5}In_{0.5}P, the thickness of which is set at 50 Å, for example. Each of the first and second guide layers is made of (Al_{0.5}Ga_{0.5})_{0.5}In_{0.5}P, the thickness of which is set at 50 Å, for example.

The second clad layer 45 is formed on one surface 44a in a thickness direction Z of the active layer 44 so as to be stacked on the entire one surface 44a with use of p-type (AlₓGa₁₋ₓ)_{Y}In_{1-Y}P, wherein the following conditions have to be satisfied: 0<X<1 and 0<Y<1. In the present embodiment, the value of X is set at 0.7, and the value of Y is set at 0.5. That is, the second clad layer 45 is made of p-type (Al_{0.7}Ga_{0.3})_{0.5}In_{0.5}P. The thickness of the second clad layer 45 is adjusted to fall in a range of from 1.0 μm to 2.0 μm, for example.

On the second clad layer 45 are formed a ridge portion 61 and a terrace portion 62. The ridge portion 61 is provided in a direction in which laser light is emitted, that is, provided at a center portion of a width direction Y perpendicular to each of a longitudinal direction X and a thickness direction Z of the semiconductor laser device 32. On both sides in the width direction Y of the ridge portion 61 are formed clad layer groove portions 63, each of which extends along the longitudinal direction X. On outer sides in the width direction Y of the clad layer groove portion 63 are formed the terrace portions 62. The ridge portion 61 and the terrace portion 62 form protrusions extending from a bottom surface 63a of the clad layer groove portion 63 to one side in the thickness direction Z.

The semiconductor laser device 32 is designed substantially surface-symmetrical about a virtual plane passing through the Y direction-wise center in parallel with the thickness direction Z. Each of the ridge portion 61 and the terrace portion 62 is formed into a substantial rectangular parallelepiped shape, and extends along the longitudinal direction X across both ends of the semiconductor laser device 32. That is to say, the ridge portion 61 is formed in a striped shape. Each thickness of the ridge portion 61 and the terrace portion 62 is selected to fall in a range of from 1.0 μm to 2.0 μm. The ridge portion 61 forms a ridge waveguide through which laser light is directed.

The ridge portion 61 is formed so as to have a predetermined length L1 when viewed in the width direction Y, which predetermined length L1 is selected to fall in a range of from 1.0 μm to 3.0 μm. More specifically, when viewed in the width direction Y, the dimension of Z direction-wise one end of the ridge portion 61, namely one end of the ridge portion 61 located away from the semiconductor substrate 42 is selected to fall in a range of from 0.5 μm to 2.5 μm, whereas the dimension of the other Z direction-wise end of the ridge portion 61 is selected to fall in a range of from 1.0 μm to 3.0 μm. When viewed in the direction perpendicular to the direction X in which the ridge portion 61 extends, the ridge portion 61 has a trapezoidal cross-sectional profile, the lower side of the trapezoid facing the semiconductor substrate 42. Note that in FIG. 2, the ridge portion 61 is shown with a quadrilateral cross-sectional profile for the sake of simplifying an understanding of the illustration.

When viewed in the width direction Y, the terrace portion 62 is formed on either side of the ridge portion 61, that is, the ridge waveguide. A predetermined first distance L2 is secured between the terrace portion 62 and the ridge portion 61. The predetermined first distance L2 is selected to fall in a range of from 10 μm to 20 μm. When viewed in the width direction Y, the terrace portion 62 is so formed as to extend outwardly from a position which is located the predetermined first distance L2 away from the ridge portion 61, to the edge of the semiconductor laser device 32.

By virtue of the terrace portion 62, it is possible to reduce the hazard of mechanical damage to the ridge portion 61 at the time of working with a wafer on which is formed a precursor of the semiconductor laser device 32 during the process of manufacture of the semiconductor laser device 32, as well as the time of mounting the semiconductor laser device 32.

In a region included in the active layer 44, on which the ridge portion 61 is stacked, is formed the stripe-shaped light-emitting region 40 extending in the longitudinal direction X. The light-emitting region 40 indicates a part which emits light by laser oscillation when the semiconductor laser device 32 is supplied with electric current. A flowing trace of carrier passing through the ridge portion 61 spreads out in the width direction Y from the ridge portion 61, so that a dimension of the light-emitting region 40 is a slightly larger than that of the ridge portion 61 when viewed in the width direction Y. The light-emitting region 40 which extends in the longitudinal direction X along the ridge portion 61, is formed between one end and the other end of the longitudinal direction X of the semiconductor laser device 32.

The cap layer 46A is formed on one surface 61a in a thickness direction Z of the ridge portion 61 of the second clad layer 45 so as to be stacked on the entire one surface 61a. The cap layer 46A is made of p-type gallium arsenide (GaAs), the thickness of which is selected to fall in a range of from 0.2 μm to 0.5 μm, for example. The cap layer 46A is employed to gain an ohmic contact with the ohmic electrode layer 48.

The terrace portion carrying layer 46B is formed on one surface 62a in a thickness direction Z of the terrace portion 62 so as to be stacked on the entire one surface 62a. The terrace portion carrying layer 46B is the same in material and thickness as the cap layer 46A.

The insulating layer 47 is stacked on one side of each of the cap layer 46A, the terrace portion carrying layer 46B, and the second clad layer 45, except for one surface 46a in a thickness direction Z of the cap layer 46A. The insulating layer 47 covers a surface 61b of the ridge portion 61 facing the terrace portion 62 and a surface 62b of the terrace portion 62 facing the ridge portion 61 when viewed in the thickness direction Z. The insulating layer 47 is formed of, for example, SiO₂, the thickness of which is selected to fall in a range of from 500 Å to 2000 Å. By virtue of the insulating layer 47, a flow of the electric current is enabled to be focused on the cap layer 46A and the ridge portion 61.

The ohmic electrode layer 48 is formed on one surface 47a in a thickness direction Z of the insulating layer 47 and one surface 46a in the thickness direction Z of the cap layer 46A so as to be stacked on the entire one surface 46a, 47a. The ohmic electrode layer 48 is made of AuZn, the thickness of which is selected to fall in a range of from 300 Å to 700 Å, for example.

The plate electrode layer 49 is electrically conductive and formed on one surface 48a in a thickness direction Z of the ohmic electrode layer 48 so as to be stacked on the entire one surface 48a. The plate electrode layer 49 is made of gold (Au), the thickness of which is selected to be 0.5 μm or more and less than 5.0 μm. By thus setting the thickness of the plate electrode layer 49, the heat generated by the light-emitting region 40 can be conducted outwardly in the width direction Y through the plate electrode layer 49 formed of Au having a high thermal conductivity, thus allowing by-passing of the heat transmission path whereby the operating current at a high temperature can be reduced. If the thickness of the plate electrode layer 49 is less than 0.5 μm, a satisfactory heat-transmission effect cannot be attained. By way of contrast, if the thickness of the plate electrode layer 49 exceeds 5.0 μm, the wafer will suffer from some warping during the formation of metal layers thereon, wherefore a stress is generated in the ridge portion 61, resulting in strain in the ridge waveguide. In light of the foregoing, by adjusting the thickness of the plate electrode layer 49 to be 0.5 μm or more and 5.0 μm or less, it is possible to attain enhancement in the effect of heat-transmission directed outward from a center portion in the width direction Y of the semiconductor laser device 32, as well as reduction of the stress given to the ridge portion 61.

The metal layer 52 including the incomplete adherent layer 51 is electrically conductive and formed on a one surface 49a in a thickness direction Z of the plate electrode layer 49 so as to be stacked on the entire one surface 49a. The metal layer 52 is made of a material of which melting point is higher than that of the solder material constituting an after-mentioned solder layer 71. The metal layer 52 is made of one or two or more substances which are selected from molybdenum (Mo), platinum (Pt), and titanium (Ti) . In the present embodiment, the metal layer 52 is made of Pt. The incomplete adherent layer 51 constitutes a part of the metal layer 52. A thickness of the metal layer 52 is selected to fall in a range of from 0.05 μm to 0.30 μm.

The complete adherent layer 53 is formed on one surface 52a in a thickness direction Z of the metal layer 52 so as to be stacked on a predetermined region of the one surface 52a. The complete adherent layer 53 is made of gold (Au). A thickness of the complete adherent layer 53 is selected to fall in a range of from 0.1 μm to 0.4 μm. The complete adherent layer 53 is formed over a region in the outermost surface of one side in the thickness direction Z of the semiconductor laser device 32, which region excludes a region where the incomplete adherent layer 51 is formed. The incomplete adherent layer 51 and the complete adherent layer 53 constitute a surface electrode of the semiconductor laser device 32.

With reference to FIG. 1, the incomplete adherent layer 51 and the complete adherent layer 53 will be described in more detail. The semiconductor laser device 32 has a light-emitting end face 32A and a light-reflecting end face 32B. The light-emitting end face 32A is formed on one end of the semiconductor laser device 32 while the light-reflecting end face 32B is formed on the other end of the semiconductor laser device 32, when viewed in a direction in which laser light is emitted, that is, in the longitudinal direction X. During operation of the semiconductor laser device 32, the laser light travels back and forth more than once between the light-emitting end face 32A and the light-reflecting end face 32B, and then is emitted from the light-emitting face 32A to outside.

The light-reflecting end face 32B is constituted by vapor-deposition in the longitudinal direction X of 10 films composed of alternate Al₂O₃ films and TiO₂ films. A thickness of each Al₂O₃ film is selected to be 100 nm while a thickness of each TiO₂ film is selected to be 75 nm. After the vapor-deposition of the 10 films, the formation of reflecting film is completed by vapor-depositing the Al₂O₃ film. A thickness of the last (outermost) Al₂O₃ film is selected to be 200 nm. A reflectivity of the laser light on the light-reflecting end face 32B is 95%. The light-emitting end face 32A is constituted by vapor-deposition of an Al₂O₃ film. A thickness of the Al₂O₃ film is selected to be 120 nm. A reflectivity of the laser light on the light-emitting end face 32A is 6%.

The incomplete adherent layer 51 is formed on a part of the outermost surface 55 of the semiconductor laser device 32, which outermost surface 55 is to be attached to the mount 72, that is, the outermost surface located the farthest away from the semiconductor substrate 42, of the deposition formed on the Z direction-wise one surface 42a of the semiconductor substrate 42. The incomplete adherent layer 51 extends over an area 60 ranging outward by a predetermined second distance L3 on either side from a virtual plane which passes through the Y direction-wise center of the light-emitting region 40 and which is perpendicular to the width direction Y. When viewed in the longitudinal direction X, a length L5 of the incomplete adherent layer 51 is shorter than a length L6 of the light-emitting region 40. A longitudinal direction of the light-emitting region 40 corresponds to the longitudinal direction X of the semiconductor laser device 32. To be more specific, the incomplete adherent layer 51 is formed on the light-emitting end where the light-emitting end face 32A is formed, and extends by the length L5 from the light-emitting end face 32A. When viewed in the longitudinal direction X, the length L6 of the light-emitting region 40 is equal to a length of the ridge portion 61.

The predetermined second distance L3 is selected to be 10 μm, so as to be 2 μm or more and less than 20 μm, for example. If the predetermined second distance L3 is 20 μm or more, the efficiency of dissipating heat is deteriorated and the operating current at a high temperature is increased, resulting in deterioration in reliability. By way of contrast, if the predetermined second distance L3 is less than 2 μm, the light-emitting region 40 suffers from strain, resulting in deterioration in reliability.

In the outermost surface 55 acting as the Z direction-wise outermost surface of the semiconductor laser device 32 located the farthest away from the semiconductor substrate 42 is formed a surface groove portion 82 which extends along the longitudinal direction X. The surface groove portion 82 is formed on either side of a Y direction-wise center portion where the ridge portion 61 is formed. The surface groove portion 82 is constituted by irregularities generated on the Z direction-wise one surface of the second clad layer 45 attributable to the ridge portion 61 and the terrace portion 62 formed on the second clad layer 45 and further the cap layer 46A stacked on the ridge portion 61 and the terrace portion carrying layer 46B stacked on the terrace portion 62, on which surface being irregular are stacked the insulating layer 47, the ohmic electrode layer 48, the plate electrode layer 49, the metal layer 52, and the complete adherent layer 53. A part located at the Y direction-wise center portion where the ridge portion 61 is formed, which part protrudes to one side in the thickness direction Z from a bottom of the surface groove portion 82, is referred to as a ridge protrusion 83. A part located on at the Y direction-wise both ends where the terrace portion 62 is formed, which part protrudes to one side in the thickness direction Z from a bottom of the surface groove portion 82, is referred to as a terrace protrusion 84.

When viewed in the width direction Y, the incomplete adherent layer 51 of the metal layer 52 is provided so as to cover at least the ridge protrusion 83. Accordingly, when viewed in the width direction Y, the incomplete adherent layer 51 of the metal layer 52 is provided so as to cover at least a part above the ridge structure 56. The incomplete adherent layer 51 extends to a Y direction-wise center of the surface groove portion 82. The ridge structure 56 contains the ridge portion 61 and a portion located at a region where the ridge portion 61 is formed, which portion is stacked on the ridge portion 61, in the semiconductor laser device 32. The ridge structure 56 ranges over an area across the both ends on the semiconductor substrate 42-side of the ridge portion 61 in the width direction Y, that is, an area indicated by a reference symbol L1 in FIG. 2. The incomplete adherent layer 51 included in the surface groove portion 82 extends from the ridge protrusion 83 by a predetermined third distance L4.

The predetermined third distance L4 is selected to be 1 μm or more and less than 19 μm. The predetermined second distance L3 is determined firstly and then, an approximate value of the predetermined third distance L4 is obtained by a calculation (L3−1 μm).

Since a length of an incomplete adherent region is shorter than the X direction-wise length L6 of the light-emitting region 40 when viewed in the longitudinal direction X of the light-emitting region 40, a part of the area 60 included in the outermost surface 55 is adhered to the solder layer 71 at a position of deposition formed on the light-emitting region 40 included in the outermost surface 55 of the semiconductor laser device 32. By so doing, also in the range 60 adjacent to the light-emitting region 40, the heat generated by the light-emitting region 40 is made to be more easily conducted to the mount 72 through the solder layer 71 to thereby enhance the efficiency of dissipating heat to the mount 72, so that the operating current at a high temperature is prevented from increasing, allowing enhancement in reliability at a high temperature.

The length L5 and the length L6 are selected so as to satisfy the following relation:
0.2×L6≦L5≦0.8×L6 . . . (1)
wherein L5 represents an X direction-wise length of the incomplete adherent layer 51 and L6 represents an X direction-wise length of the light-emitting region 40.

For example, the X direction-wise length L6 of the light-emitting region 40 is selected to be 1500 μm, and the X direction-wise length L5 of the incomplete adherent layer 51 is selected to be 1000 μm.

The back-side electrode layer 54 is formed on the other surface portion in the thickness direction Z of the semiconductor substrate 42 so as to be stacked on the entire surface of the other surface 42b in the thickness direction Z of the semiconductor substrate 42. The back-side electrode layer 54 is made of gold (Au). A thickness of the back-side electrode layer 54 is different from the thickness of the plate electrode layer 52, and selected to fall in a range of from 1000 Å to 3000 Å.

Next, a method of preparing the semiconductor laser device 32 will be described. At the outset, on one surface of a precursor of the semiconductor substrate 42 ranging in thickness from 300 μm to 350 μm are successively stacked the 2.0 μm-thick first clad layer 43, the active layer 44, a 1.5 μm-thick first precursor layer made of p-type (Al_{0.7}Ga_{0.3})_{0.5}In_{0.5}P for forming the second clad layer 45, and a 0.5 μm-thick second precursor layer made of GaAs for forming the cap layer 46A and the terrace portion carrying layer 46B in the order named by means of epitaxial growth technique using a metalorganic chemical vapor deposition (MOCVD for short) apparatus or a molecular beam epitaxial (MBE for short) apparatus. In forming the active layer 44, the first, second and third well layers are each set at 60 Å in thickness, the first and second barrier layer are each set at 50 Å in thickness, and the first and second guide layers are each set at 500 Å in thickness.

Next, as shown in FIG. 2, parts of the first and second precursor layers are removed by means of photolithography and etching techniques to create the ridge portion 61, the terrace portion 62, the cap layer 46A, and the terrace portion carrying layer 46B.

Next, a layer made of SiO₂ is stacked on the second clad layer 45, the cap layer 46A, and the terrace portion carrying layer 46B. Subsequently, of the layer made of SiO₂, the portion located on the Z direction-wise one surface 46a of the cap layer 46A is removed by means of photolithography and etching techniques to create the insulating layer 47.

Next, the ohmic electrode layer 48 is stacked on the insulating layer 47 and the cap layer 46A by vapor-deposition.

Next, the other Z direction-wise surface of the precursor of the semiconductor substrate 42 is polished to the thickness ranging from 50 μm to 130 μm, thereby constituting the semiconductor substrate 42.

Next, on the other Z direction-wise surface 42b of the semiconductor substrate 42 is formed the back-side electrode layer 54. Then, the ohmic electrode layer 48 and the back-side electrode layer 54 are subjected to an alloying process in an atmosphere of nitrogen gas.

Next, the ohmic electrode layer 48 is subjected to power feeding to carry out electrolytic Au plating for a predetermined period of time. In this way, there is formed the plate electrode layer 49 having a thickness of 0.5 μm or more and less than 5.0 μm. By adjusting the thickness of the back-side electrode layer 54 to the above-stated level, it is possible to alleviate the stress generated in stacking the plate electrode layer 49 on an opposite side of the semiconductor substrate 42 from a side on which the back-side electrode layer 54 is formed.

Next, Pt is vapor-deposited onto Z direction-wise one surface 49a of the plate electrode layer 49 to create the metal layer 52. Subsequently, Au is vapor-deposited onto Z direction-wise one surface 52a of the metal layer 52 to create a third precursor layer.

Next, a resist is applied onto Z direction-wise one surface of the third precursor layer. After that, part of the resist overlying the metal layer 52 is removed by means of photolithography and etching techniques to expose the part of the third precursor layer which is stacked on a certain region of the metal layer 52 to be formed into the incomplete adherent layer 51. In this way, a resist pattern layer is formed.

Next, the part of the third precursor layer which is not covered with the resist pattern layer is removed by means of etching technique so that part of the metal layer 52 is exposed. The exposed part of the metal layer 52, which is not covered with the third precursor layer, constitutes the incomplete adherent layer 51. Moreover, upon part of the third precursor layer and the resist pattern layer being removed, the complete adherent layer 53 is created in a region excluding the incomplete adherent layer 51. Next, the light-emitting face 32A and the light-reflecting end face 32B will be formed.

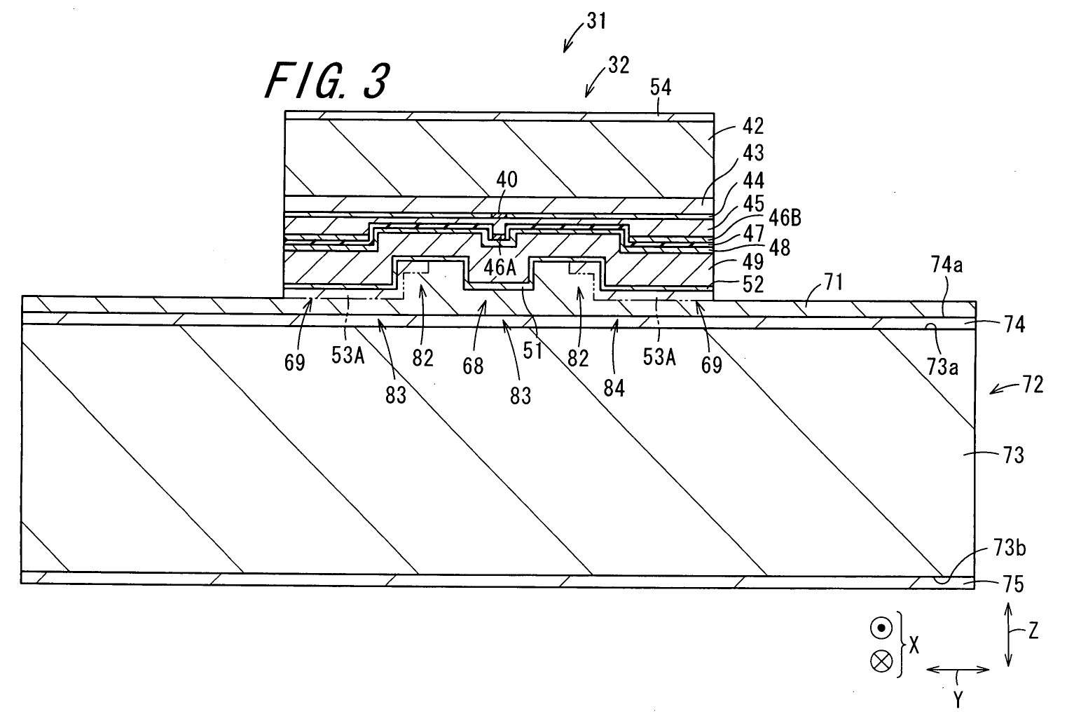

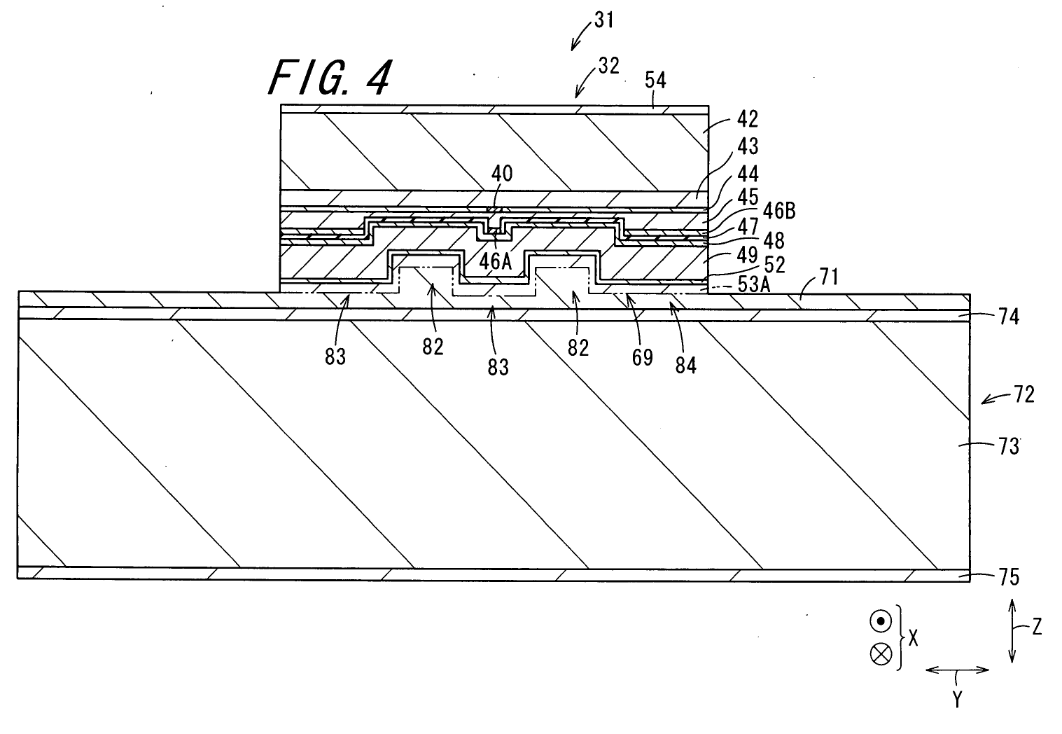

FIG. 3 is a sectional view of the semiconductor laser device 32 adhered to the mount 72 via the solder layer 71 when seen from the line II-II of the semiconductor laser apparatus 31. FIG. 4 is a sectional view of the semiconductor laser device 32 adhered to the mount 72 via the solder layer 71 when seen from the line III-III of the semiconductor laser apparatus 31. FIG. 3 is a sectional view taken along a direction perpendicular to the longitudinal direction X, relating to a part where an incomplete adherent region 68 is formed on the outermost surface of semiconductor laser device 32 to which the solder layer 71 is applied. FIG. 4 is a sectional view taken along a direction perpendicular to the longitudinal direction X, relating to a part where only a complete adherent region 69 is formed on the outermost surface of the semiconductor layer device 32. A direction in which the semiconductor laser device 32, the solder layer 71, and the mount 72 are stacked, is the thickness direction Z.

The semiconductor laser device 32 can be mounted onto the mount 72 by applying a solder material to the outermost surface 55, that is, by applying a solder material to the incomplete adherent layer 51 and the complete adherent layer 53, by means of die bonding. The solder material is made of AuSn. In the present embodiment, the solder material has an Au content of 70% and a Sn content of 30%. The solder layer 71 is made of the solder material.

The mount 72 is constituted by a heat sink. The mount 72 is composed of a mount main body 73, a first mounting electrode layer 74, and a second mounting electrode layer 75. The first mounting electrode layer 74 is formed on one surface 73a of a thickness direction Z of the mount main body 73 so as to be stacked on the entire one surface 73a. The second mounting electrode layer 75 is formed on the other surface 73b of the thickness direction Z of the mount main body 73 so as to be stacked on the entire surface of the other surface 73b. Each of the one surface 73a and the other surface 73b is formed into a plane when viewed in the thickness direction X of the mount main body 73. Each of the first mounting electrode 74 and the second mounting electrode 75 is formed so as to have a predetermined thickness. The Z direction-wise one surface 74a of the first mounting electrode layer 74 is formed into a plane. The mount main body 73 is made of a material having high electrical conductivity and also high thermal conductivity, such as aluminum nitride (AlN) and silicon carbide (SiC), the material of which thermal expansion coefficient is approximate to that of the semiconductor substrate 42. The first mounting electrode layer 74 and the second mounting electrode layer 75 are made of a material having high electrical conductivity and also high thermal conductivity, such as Au, including a metallic material which can be alloyed with the solder material. By use of the mount main body 73 made of a material having a thermal expansion coefficient approximate to that of the semiconductor substrate 42, the respective layers of the semiconductor sandwiched between the mount main body 73 and the semiconductor substrate 42 have reduced stress imparted thereto, which is caused by a difference in thermal expansion coefficient between the semiconductor laser apparatus 31 and the mount main body 73 when the semiconductor layer apparatus 31 is attached to the mount main body 73 by heat. By so doing, the degree of strain in the light-emitting region 40 can be reduced.

The semiconductor laser device 32 is die-bonded to the mount 72 under predetermined die-bonding conditions including a loading condition as to the level of load application required to mount the semiconductor laser device 32 onto the mount 72 and a heating condition as to the level of heat application required to mount the semiconductor laser device 32 onto the mount 72.

Application of a physical load is necessary to press the semiconductor laser device 32 against the solder material applied to the mount 72. However, if an unduly heavy load, for example, a load of 1.0 N (newton) is imposed on the semiconductor laser device 32, the inner structure thereof such as the ridge waveguide will be subjected to a high pressing stress, thus causing the strain in the ridge waveguide and, as the worst case, there may occur breakage of the semiconductor laser device 32 in itself. By way of contrast, if an unduly light load, for example, a load of 0.05 N is imposed, the semiconductor laser device 32 cannot be pressed sufficiently against the solder material applied to the mount 72, thus causing a failure of bonding and eventually causing separation. Although it will thus be seen that the mounting load is preferably adjusted to be more than 0.05 N and less than 1.0 N, from the standpoint of achieving mounting successfully with minimum loading, it is more preferable that the mounting load is adjusted to fall in a range of from, for example, 0.1 N to 0.3 N so that not a heavy load region but a light load region is set.

Moreover, application of heat is necessary to cause the solder material applied onto the mount 72 to melt so that the Au-made complete adherent layer 53 present on the outermost die-bonded surface of the semiconductor laser device 32 can be alloyed with the solder material. The mount 72 is placed on a heater to effect heating. At this time, if the mount 72 is heated excessively, for example, if it is heated at 360° C. (degree) for 30 s (seconds) and is thereafter forcibly cooled down for one second to approximately 200° C. with use of a blower, then a stress will be developed in the layer stacking arrangement existing within the semiconductor laser device 32 due to layer peeling and separation resulting from differences in thermal expansion coefficient, variation in physical properties, an alloying reaction, or other factors. This results in occurrence of strain. By way of contrast, if the mount 72 is heated insufficiently, for example, if it is heated at 280° C. for 0.3 s and is thereafter forcibly cooled down for one second to approximately 200° C. with use of a blower, then the semiconductor laser device 32 cannot be die-bonded properly to the solder material applied to the mount 72 because of a failure of alloying, thus causing separation. In light of the foregoing, it is preferable that the mount 72 is heated at a temperature of more than 200° C. and less than 360° C. for more than 0.3 second and less than 30 seconds. From the standpoint of achieving bonding successfully with minimum heating, the heating condition should preferably be at 300° C. and for approximately 2 seconds.

The heating temperature condition depends to a large degree on the thickness of the complete adherent layer 53 present on the outermost die-bonded surface of the semiconductor laser device 32. By setting the heating temperature at 300° C. and the heating duration at approximately 2 seconds in consideration of minimum heating, it is possible to reduce the thickness of the complete adherent layer 53 to, for example, 0.12 μm, and thereby allow the complete adherent layer 53 to be alloyed in a shorter period of time.

An alloying reaction between the solder material AuSn and Au constituting the complete adherent layer 53 starts with a heat application onto the mount 72 while the semiconductor laser device 32 is pressed against the solder material under the predetermined loading and heating conditions. In an alloying process of AuSn and Au, at first the solder material made of AuSn is caused to melt by heating, and the molten AuSn is adhered to the surface of the complete adherent layer 53, and then, as the heating process continues, the adherent AuSn is diffused into the complete adherent layer 53. As to the direction of diffusion, AuSn travels in the direction of thickness of the complete adherent layer 53, and then starts to diffuse at certain several points (diffusion points) on the surface of the complete adherent layer 53. As the heating process continues further, the number of the diffusion points is increased and simultaneously the diffusion point changes its shape from a spot to a circle. The speed and depth at which AuSn travels in the thickness direction Z of the complete adherent layer 53 depend upon the ratio in absolute amount between the solder material AuSn and Au constituting the complete adherent layer 53, namely the mass ratio, and the level of heating. The time to be spent in completing the diffusion also depends upon the aforementioned factors. By increasing the amount of the solder material relatively to the amount of Au constituting the complete adherent layer 53 and also raising the level of heating, it is possible to allow the complete adherent layer 53 to be alloyed instantly on contact with AuSn. Accordingly, the complete adherent layer 53 present on the outermost die-bonded surface of the semiconductor laser device 32 is formed in the manner as described hereinabove, and the amount of the solder material is increased. In this state, the heating operation is discontinued at the instant when AuSn starts to diffuse, and the diffusion is thereupon no longer in process.

Of one outermost surface of the semiconductor laser device 32 in the thickness direction Z of the semiconductor substrate 42, the outermost surface which is the farthest away from the semiconductor substrate 42, the incomplete adherent region 68 where the Pt-made incomplete adherent layer 51 is formed, contains no Au and therefore, the solder material made of AuSn makes intimate contact with the incomplete adherent layer 61 whereas almost no alloying reaction takes place therebetween. The solder material AuSn applied to the mount 72 is alloyed only with the entire complete adherent layer 53 to thereby form an alloyed layer 53A which is obtained by an alloying process between the complete adherent layer 53 and the solder material.

There are formed the Pt-made metal layer 52, the Au-made plate electrode layer 49 and ohmic electrode layer 48, and the like layers as base layers for the complete adherent layer 53. These base layers are also subjected to the influence of stress given to the complete adherent layer 53 when alloyed with the solder material. That is, pressing force and pulling force are applied to the base layers. Of the stress, the pressing force arises when the solder material is caused to expand through application of heat, whereas the pulling force arises when the heated solder material is cooled down after the solder material has been heated. Accordingly, so long as the solder material is caused to expand, makes contact with the semiconductor laser device 32 and is caused to contract in a uniform manner, the semiconductor laser device 32 is subjected to a uniform stress, which results in reduction in the degree of strain. This makes it possible to bond the semiconductor laser device 32 in substantially bare chip (raw chip) form to the mount 72. In reality, however, the solder material is caused to expand and contract differently from part to part. Therefore, during the heating process, the semiconductor laser device 32 is subjected partly to a strong pressing force and partly to a weak pressing force. This gives rise to lack of uniformity in the alloying reaction, wherefore a stress is generated locally. As the uneven alloying reaction is going on, the heating is discontinued to effect cooling, and the solder material thereupon starts to contract. At this time, the semiconductor laser device 32 is subjected partly to a strong pulling force and partly to a weak pulling force, in addition to strong and weak pressing forces.

Note that AuSn is a solder material of one type that is hard to be alloyed with the Pt-made incomplete adherent layer 51 in a temperature range of from 300° C. to 400° C. in which AuSn is thermally bondable. Accordingly, of the outermost surface 55 of the semiconductor laser device 32, the complete adherent region 69 where the complete adherent layer 53 and the solder material are alloyed with each other, has an increased strength of bonding with the solder layer 71 as described above when the semiconductor laser device 32 is being mounted onto the mount 72, causing large stress. Of the outermost surface 55 of the semiconductor laser device 32, by way of contrast, the incomplete adherent region 68 where the incomplete adherent layer 51 is formed, has a decreased strength of bonding with the solder layer 71 because the incomplete adherent layer 51 and the solder material are hardly alloyed with each other under the above-described die-bonding conditions when semiconductor laser device 32 is being mounted onto the mount 72, allowing reduction in stress imparted to the light-emitting region 40 when the solder material undergoes the thermal expansion and thermal contraction.

During operation of the semiconductor laser apparatus 31, the semiconductor laser device 32 generates heat which is then conducted to the solder layer 71 and the mount 72, with the result that the semiconductor laser device 32, the solder layer 71, and the mount 72 undergo the thermal expansion. At the time, differences in thermal expansion coefficient among the semiconductor laser device 32, the solder layer 71, and the mount 72 cause the stress imposed on the light-emitting region 40. In this case, by virtue of an incomplete bonding between the incomplete adherent layer 51 and the solder layer 71, it is possible to reduce the stress generated by the difference in thermal expansion coefficient between the incomplete adherent layer 51 and the solder layer 71, thereby reducing the stress being imparted from the incomplete adherent layer 51 to the light-emitting region 40, with the result that the degree of strain in the light-emitting region 40 can be reduced.

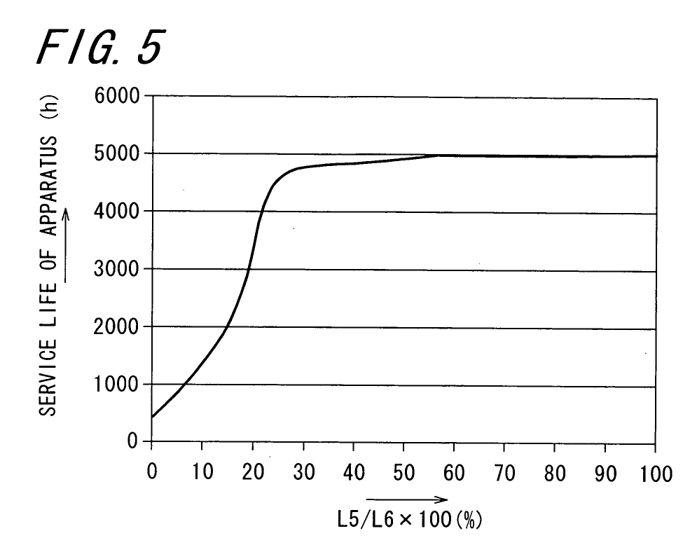

FIG. 5 is a graph showing the relationship between a ratio of a length of incomplete adherent region 68 to a length of light-emitting region 40 when viewed in the longitudinal direction X, and a service life of the semiconductor laser apparatus 31. At the outset, the above-described semiconductor laser apparatus 31 was produced, and its service life was measured with different ratios of the length of incomplete adherent region 68 to that of light-emitting region 40 when viewed in the longitudinal direction X, that is, different ratios of the X direction-wise length of incomplete adherent layer 51 to the X direction-wise length of light-emitting region 40. In FIG. 5, a horizontal axis represents the ratio of the length of incomplete adherent region 68 to that of light-emitting region 40 when viewed in the longitudinal direction X, that is, a value obtained by a calculation L5/L6×100 (%), and a vertical axis represents the length of service life (h). The measurement was conducted in a manner that the produced semiconductor laser apparatus 31 was placed in an atmosphere of 75° C. to supply the semiconductor laser apparatus 31 with a pulse current so that optical output of 300 mW can be obtained.

As the incomplete adherent region 68 is larger, that is, as the value L5/L6 is larger, the service life of the apparatus tends to be enhanced. However, if the value obtained by the calculation L5/L6×100 (%) is less than 20%, the service life of the apparatus is drastically deteriorated to be short. A reason for the shortened service life of the apparatus is that the value obtained by the calculation L5/L6×100 (%) less than 20% results in increased strain of the light-emitting region 40, leading an increase of crystal defects in the light-emitting region 40 during application of current. Accordingly, in order to enhance the service life of the apparatus, the ratio of the length of incomplete adherent region 68 to that of the light-emitting region 40 when viewed in the longitudinal direction X only needs to be 20% or more.

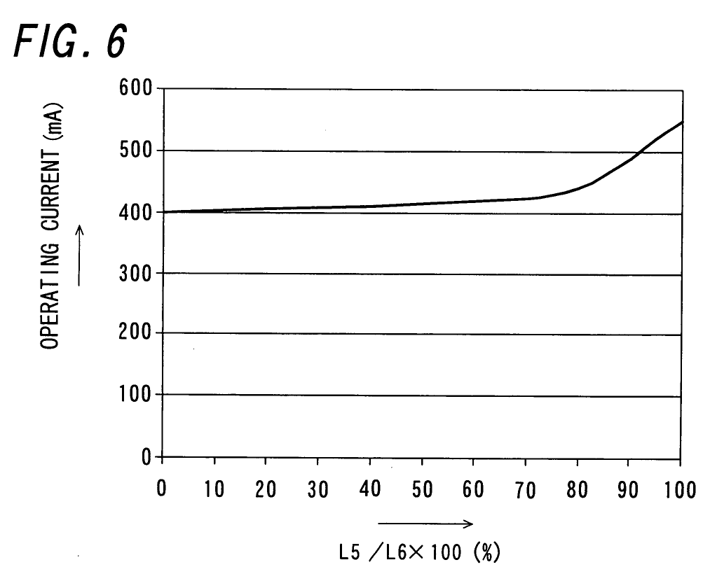

FIG. 6 is a graph showing the relationship between the ratio of the length of incomplete adherent region 68 to that of light-emitting region 40 when viewed in the longitudinal direction X, and an operating current of the semiconductor laser apparatus 31. The above-described semiconductor laser apparatus was produced, and its operating current was measured with different ratios of the length of incomplete adherent region 68 to that of light-emitting region 40 when viewed in the longitudinal direction X. In FIG. 6, a horizontal axis represents the ratio of the length of incomplete adherent region 68 to that of light-emitting region 40 when viewed in the longitudinal direction X, that is, a value obtained by a calculation L5/L6×100 (%), and a vertical axis represents a level of a driving current (mA) . The measurement of the driving current was conducted in a manner that the produced semiconductor laser apparatus 31 was placed in an atmosphere of 75° C. to supply the semiconductor laser apparatus 31 with a pulse current so that optical output of 300 mW can be obtained.

As the incomplete adherent region 68 is larger, that is, as the value L5/L6 is larger, the operating current of the apparatus tends to be increased. However, it can be seen that, if the value obtained by the calculation L5/L6 ×100 (%) is made so large as to exceed 80%, the operating current is drastically increased, with the result that a problem arises in reliability at a high temperature. In order to prevent the operating current at a high temperature from increasing, the ratio of the length of incomplete adherent region 68 to that of the light-emitting region 40 when viewed in the longitudinal direction X only needs to be 80% or less.

In the semiconductor laser device 32 according to the embodiment, the ratio of the length of incomplete adherent region 68 to that of light-emitting region 40 when viewed in the longitudinal direction X, that is, the value obtained by the calculation L5/L6×100 (%), is selected to be 20% or more and 80% or less, in other words, the above-stated formula (1) is satisfied, whereby the service life of the apparatus can be prevented from decreasing and the operating current during operation at a high temperature can be prevented from increasing. As a result, it is possible to provide a semiconductor laser apparatus having a longer service life, of which operating reliability at a high temperature is enhanced.

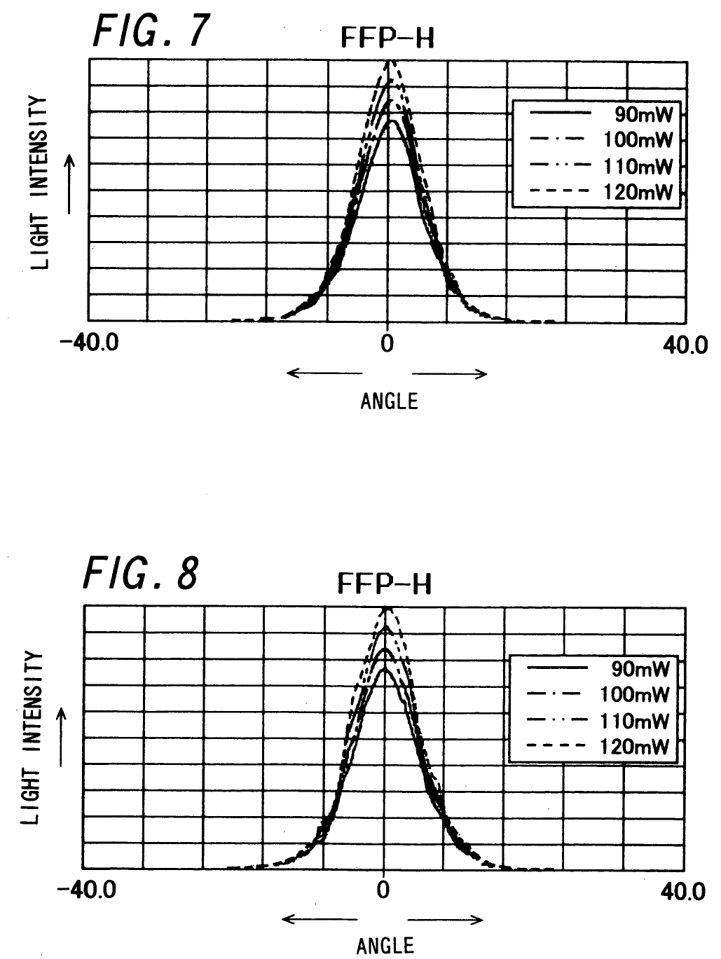

FIG. 7 is a graph showing a radiation pattern of emitted light of the semiconductor laser apparatus 31 according to the embodiment. FIG. 8 is a graph showing a radiation pattern of emitted light of a semiconductor laser apparatus of a comparative example. FIG. 7 and FIG. 8 respectively show radiation patterns at optical outputs of 90 mW, 100 mW, 110 mW, and 120 mW. The radiation pattern is represented in a form of a far field pattern (FFP for short) along a horizontal direction, that is, a direction which is parallel to a Z direction-wise surface of the semiconductor substrate 42. In FIG. 7 and FIG. 8, the radiation pattern obtained at optical output of 90 mW is shown in a solid line, the radiation pattern obtained at optical output of 100 mW is shown in a chain line, the radiation pattern obtained at optical output of 110 mW is shown in a two-dot chain line, and the radiation pattern obtained at optical output of 120 mW is shown in a dotted line. In this case, a value obtained by the calculation L5/L6×100 (%) is 67%. In each of FIG. 7 and FIG. 8, a horizontal axis represents a radiation angle, and a vertical axis represents light intensity.

The semiconductor laser apparatus 31 according to the embodiment and the semiconductor laser apparatus of the comparative example are different only in a region where the incomplete adherent region 68 is formed. In the semiconductor laser apparatus of the comparative example, the incomplete adherent region 68 is formed on the light-reflecting end face 32B-side, and the complete adherent region 69 is formed on the light-emitting end face 32A-side.

It can be seen that the radiation pattern shown in FIG. 8 obtained by the semiconductor laser apparatus of the comparative example includes distortions which are larger at a larger output, whereas the radiation pattern shown in FIG. 7 obtained by the semiconductor laser apparatus 31 according to the embodiment includes no distortions. By providing the incomplete adherent region 68 at the light-emitting end, that is, by designing a L5-long region extending from the light-emitting end face 31A to be the incomplete adherent region 68, it is possible to prevent the distortions from arising in the radiation pattern. In a part of the light-emitting region 40 extending in a resonance direction, of the semiconductor laser device 32, where the incomplete adherent region 69 is formed, that is, a part on which the alloyed layer 53A is stacked, light passing through the light-emitting region 40 is influenced by refractive index fluctuation caused by internal stress, with the result that the distortions arise in the radiation pattern. By contrast, in a part of the light-emitting region 40 on which the incomplete adherent layer 51 is stacked, light passing through the light-emitting region 40 is less easily influenced by the refractive index fluctuation by virtue of a small amount of the internal stress, allowing reduction of the distortions arising in the radiation pattern.

Although a part of the light-emitting region 40 is influenced by the refractive index fluctuation, the influence of the refractive index fluctuation is alleviated while the light passes through the part of the light-emitting region 40 where the incomplete adherent region 68 is formed. As a result, the light being emitted from the emitting end has no influence of the refractive index fluctuation, causing no distortions in the radiation pattern.

When the length of L5 is short, the radiation pattern has large distortions. In order not to generate distortions in the radiation pattern, it is desirable that the incomplete adherent region 68 range from the light-emitting end face 32A by 100 μm or more.

As described above, in the semiconductor laser apparatus 31, the above-stated incomplete adherent region 68 is formed on the outermost surface 55 to which the solder layer 71 is to be applied, thereby allowing reduction of the internal stress of the semiconductor laser device 32, with the result that the service life of the apparatus can be enhanced. Furthermore, the complete adherent region 69 is also formed so that there can be an enhanced efficiency of dissipating heat from the semiconductor laser device 32 to the mount 72 via the solder layer 71, with the result that the operating current at a high temperature can be reduced.

Further, in the semiconductor laser apparatus 31, upon mounting the semiconductor laser device 32 onto the mount 72, the solder material is applied to the entire Z direction-wise surface of the semiconductor laser device 32 and adhered thereto. Accordingly, the solder material need not be applied partly to the outermost surface 55 so that the manufacturing process is simplified.

Although the complete adherent layer 53 is made of Au in the present embodiment, the complete adherent layer 53 in another embodiment of the invention may be made of a material predominantly containing Au, of which Au content is 60% to 90%. Also in this case, the same effects can be obtained. And furthermore, the stress caused by the alloying process between the complete adherent layer 53 and the solder material can be prevented so that the degree of strain in the light-emitting region 40 can be reduced.

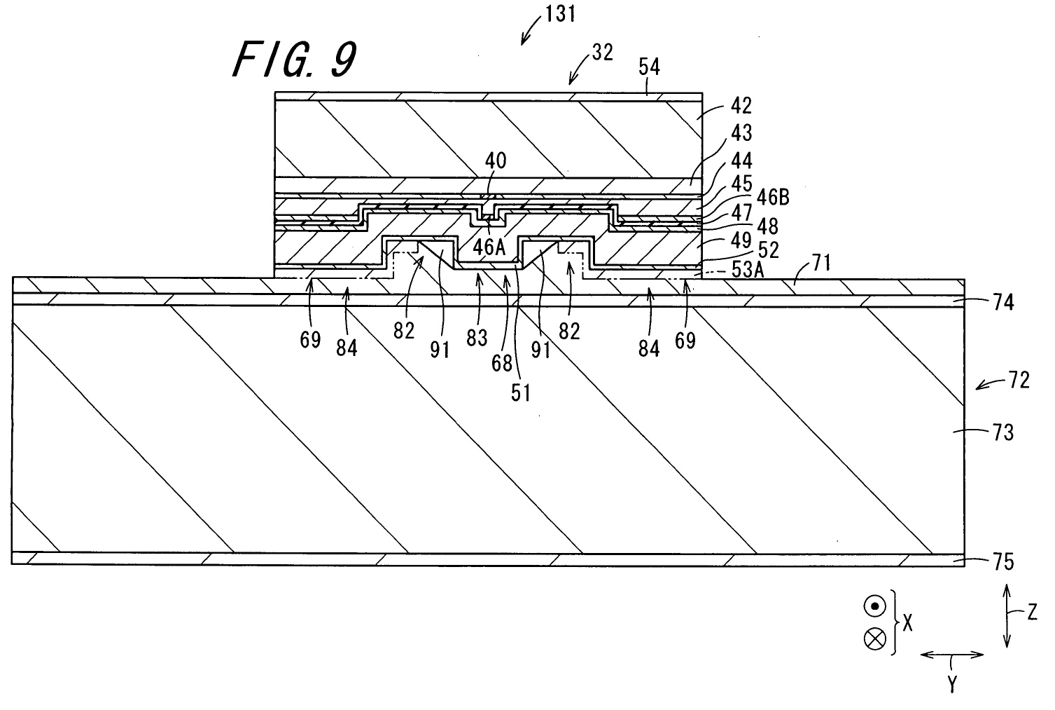

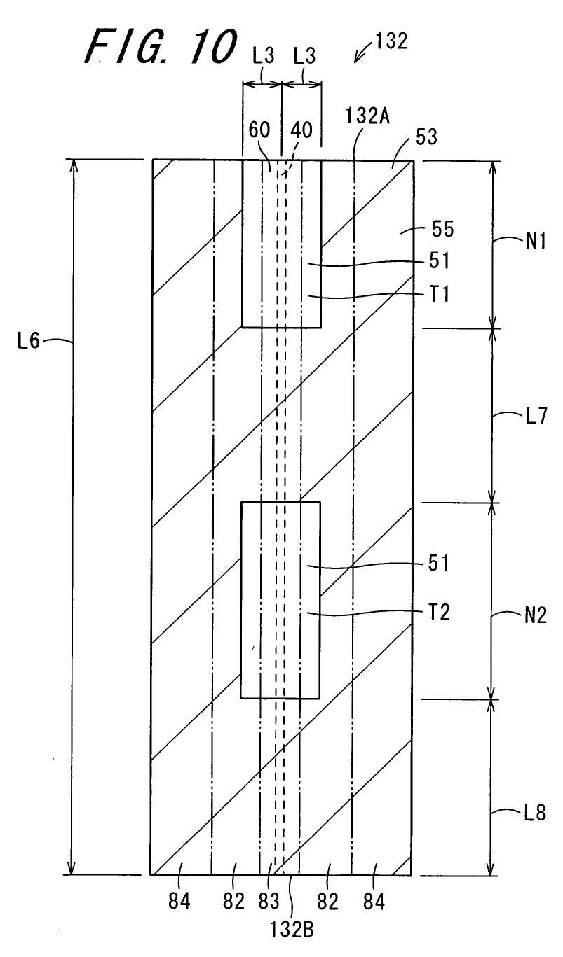

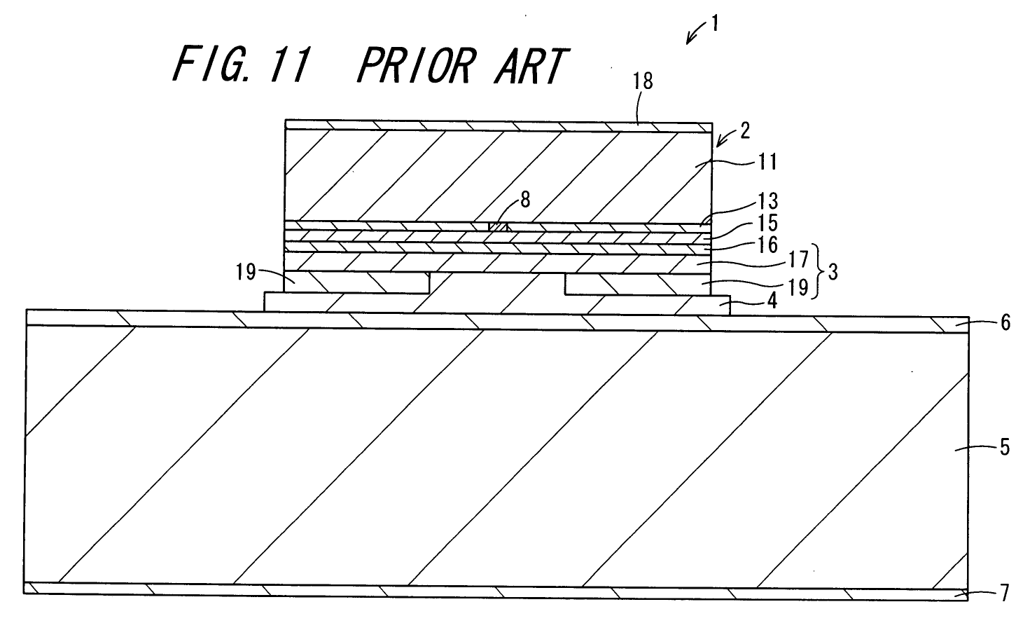

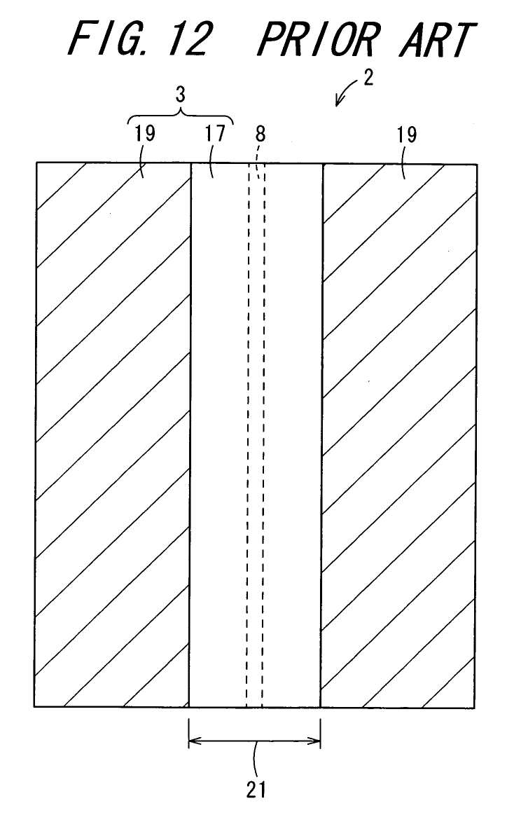

FIG. 9 is a sectional view showing a semiconductor laser apparatus 131 according to another embodiment of the invention. The semiconductor laser apparatus 131 according to the present embodiment has basically the same structure as the semiconductor laser apparatus 31 according to the preceding embodiment. Accordingly, the constituent components that play the same or corresponding roles as in the semiconductor laser apparatus 31 will be denoted by the same reference symbols, and descriptions thereof will be omitted while only different parts will be described.

In the semiconductor laser apparatus 131, a cavity 91 is created between the incomplete adherent layer 51 and the solder layer 71. The cavity 91 is formed in the surface groove portion 82 of the semiconductor laser device 32. The Z direction-wise one surface of the ridge protrusion 83 contacts the solder layer 71, but a part of the surface groove portion 82 where the incomplete adherent layer 51 is formed, does not contact the solder layer 71. The cavity 91 is formed between the incomplete adherent layer 51 and the solder layer 71 so as to extend from one end to the other end in the longitudinal direction X of the incomplete adherent layer 51.

In the embodiment, the incomplete adherent layer 51 is made of Mo, the complete adherent layer 53 is made of Au, and the solder layer 71 is made of AuSn. Upon mounting the semiconductor laser device 32 onto the mount 72, the mount 72 is placed at a lower position in a direction of gravitational force and then, the semiconductor laser device 32 is mounted onto the mount 72 from an upper position in the direction of gravitational force. The semiconductor laser device 32 having a ridge structure is adhered to the mount 72 by use of the solder material under the above-mentioned die-bonding conditions, and the Au-made complete adherent layer 53 and the AuSn-made solder material are easily alloyed with each other to thereby form the alloyed layer 53A whereas the Mo-made incomplete adherent layer 51 and the AuSn-made solder material are not alloyed with each other at all. Since the wettability between Mo and AuSn is low, the solder material moves to the mount 72-side by gravity before coagulated in the surface groove portion 82, whereby the cavity 91 can be formed between the incomplete adherent layer 51 and the solder layer 71 in the surface groove portion 81. The cavity 91 is a space surrounded by a Y direction-wise surface portion of the ridge protrusion 83, a surface portion of the bottom of surface groove portion 82 where the incomplete adherent layer 51 is formed, and the solder layer 71. A surface of the solder layer 71 facing the cavity 91 is inclined in a substantially linear form from the Z direction-wise surface portion of the ridge protrusion 83 to an end portion on the ridge protrusion 83-side of the complete adherent layer 53. In the embodiment, the incomplete adherent layer is a non-alloying layer, and the incomplete adherent region is a non-alloying region.

Also in the semiconductor laser apparatus 131 according to the embodiment, it is possible to obtain effects which are the same as those obtained in the above-described semiconductor laser apparatus 31. Moreover, the cavity 91 contributes to the reduction of the stress imparted laterally in the width direction Y to the ridge protrusion 83 of the semiconductor laser device 32. This makes it possible to further reduce the internal stress of the semiconductor laser device 32, allowing further extension of the length of service life of the semiconductor laser apparatus 31.

Although the efficiency of dissipating heat from the incomplete adherent layer 51 to the mount 72 through the solder layer 71 is slightly decreased due to the concavity 91, the efficiency of heat dissipation in the complete adherent region 69 is high enough to provide a semiconductor laser apparatus having a long service life, in which the operating current during operation at a high temperature can be prevented from increasing and of which operating reliability at a high temperature is enhanced, as in the case of the semiconductor laser apparatus 31 according to the preceding embodiment.

FIG. 10 is a plan view of a semiconductor laser device 132 provided in the semiconductor laser apparatus according to still another embodiment of the invention when seen from a side to be mounted onto the mount 72. The semiconductor laser apparatus according to the present embodiment and the above-described semiconductor laser apparatus 31 shown in FIGS. 1 to 4 have basically the same structure except only for regions for forming the complete adherent layer 53 and the incomplete adherent layer 51 located on the outermost surface of semiconductor laser device to which the solder layer 71 is applied. Accordingly, the constituent components that play the same or corresponding roles as in the semiconductor laser apparatus 31 will be denoted by the same reference symbols, and descriptions thereof will be omitted while only different parts will be described.

In the semiconductor laser device 132, the incomplete adherent layer 51 and the complete adherent layer 53 of the outermost surface 55 of the semiconductor laser device 132 are provided alternately along the longitudinal direction X of the semiconductor laser device 132 in an area 60 ranging outward by the predetermined second distance L3 on either side from a virtual plane which passes through the Y direction-wise center of the light-emitting region 40 and which is perpendicular to the width direction Y.

Assume that in the order from the light-emitting end face 132A to the light-reflecting end face 132B, the incomplete adherent layers 51 distanced away from each other along the longitudinal direction X are referred to as first to n-th (symbol n is an integer of 2 or more) incomplete adherent layers T1, T2, . . . , (Tn-1), Tn, and X direction-wise lengths of the first to n-th incomplete adherent layers T1, T2, . . . , (Tn-1), Tn are represented respectively by N1, N2, . . . , (Nn-1), Nn. In this case, the sum of X direction-wise lengths N1, N2, . . . , (Nn-1), Nn of the first to n-th incomplete adherent layers T1, T2, . . . , (Tn-1), Tn, that is to say, a value obtained by the calculation N(N=N1+N2+. . . +Nn−1+Nn) is selected so as to satisfy the following relation:
0.2×L6≦N≦0.8×L6 . . . (2)
wherein L6 represents the X direction-wise length of the light-emitting region 40.

The first incomplete adherent layer T1 is formed in an area which is located at a distance N1 from the light emitting end face 132A. The X direction-wise lengths N1, N2, . . . , (Nn-1), Nn of the first to n-th incomplete adherent layers T1, T2, . . . , (Tn-1), Tn are respectively selected to be 100 μm, so as to be 50 μm or more and less than 300 μm, for example. The lengths N1 to Nn are adjusted so as to equalize the internal stress of the semiconductor laser device, thereby equalizing a distribution of internal temperature.

In the present embodiment, the first incomplete adherent layer T1 and the second adherent layer T2 are formed. In the outermost surface of semiconductor laser device 132 to which the solder layer 71 is applied, the first incomplete adherent layer T1 is formed in an area ranging from the light-emitting end face 132A along the longitudinal direction X by the length N1, and the second incomplete adherent layer T2 is formed in an area ranging from a position at a predetermined distance L7 from an end of the first incomplete adherent layer T1 on the light-reflecting end face 132B-side along the longitudinal direction X by the length N2. An end of the second incomplete adherent layer T2 on the light-reflecting end face 132B-side and the light-reflecting end face 132B are distanced away from each other by a predetermined distance L8. Accordingly, the first incomplete adherent layer T1 and the second incomplete adherent layer T2 are formed in the range 60 so that a calculation L6=N1+L7+N2+L8 is satisfied.

The values N1, L7, N2, and L8 are preferably selected to be substantially the same for the sake of equalization of the internal stress of the semiconductor laser device and equalization of the distribution of internal temperature.

Upon mounting the above-described semiconductor laser device 132 onto the mount 72 by use of the AuSn-made solder material under the above-stated heating conditions, the complete adherent layer 53 and solder material of the outermost surface are alloyed with each other to from an alloyed layer while the first and second incomplete adherent layers T1 and T2 and the solder material are not alloyed with each other. Accordingly, a part where the complete adherent layer 53 is formed turns out to be a complete adherent region, and a part where the incomplete adherent layer 51 is formed turns out to be an incomplete adherent region. As a result, the internal stress of the semiconductor laser device 132 can be dispersed from the area 60 in the longitudinal direction X of the light-emitting region 40 and furthermore, the heat transmission paths of high heat conduction can be dispersed in the longitudinal direction of the light-emitting region 40. Accordingly, the internal stress imparted to the light-emitting region 40 is equalized as much as possible when viewed in the longitudinal direction X so that the distortions arising in the radiation pattern can be reduced. Further, the heat conduction from the light-emitting region 40 to the mount 72 is equalized as much as possible when viewed in the longitudinal direction X so that a temperature of the light-emitting region 40 can be made as uniform as possible. As a result, it is possible to further prevent the operating current at a high temperature from increasing.

Although the incomplete adherent layer and the complete adherent layer are formed in the outermost surface to which the solder layer is applied, of the semiconductor laser device having the ridge structure in the above-described embodiments, the incomplete adherent layer and the complete adherent layer may be formed in the outermost surface to which the solder layer is applied, of the semiconductor laser device having a rib structure. Also in a semiconductor laser apparatus provided with the semiconductor laser device having a rib structure, it is possible to obtain effects which are the same as those obtained in the semiconductor laser apparatus provided with the semiconductor laser device having the ridge structure.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A semiconductor laser apparatus comprising:
a semiconductor laser device having a stripe-shaped light emitting region; and
a mount to which the semiconductor laser device is adhered via a solder layer,
wherein an outermost surface of the semiconductor laser device to which the solder layer is applied is electrically conductive and the outermost surface has an incomplete adherent region which is incompletely adhered to the solder layer, extends in a width direction perpendicular to a longitudinal direction of the light-emitting region and a stacking direction of the semiconductor laser device, the solder layer and the mount, outwardly to either side by a predetermined distance from a virtual plane which passes through a center of the light-emitting region and is perpendicular to the width direction, and which incomplete adherent region has a longitudinal length shorter than that of the light-emitting region, and the outermost surface has a complete adherent region which is adhered to the solder layer and extends over an area of the outermost surface excluding the incomplete adherent region.

2. The semiconductor laser apparatus of claim 1, wherein the incomplete adherent region is formed at a light-emitting end of the semiconductor laser device.

3. The semiconductor laser apparatus of claim 1, wherein a ratio of the longitudinal length of the incomplete adherent region to that of the light-emitting region is 20% or more and 80% or less.

4. The semiconductor laser apparatus of claim 1, wherein a part included in the incomplete adherent region of the outermost surface is made of one or more substances selected from a group consisting of Mo, Pt, and Ti, and
wherein a part included in the complete adherent region of the outermost surface is made of alloy of a material containing Au and a solder material made of AuSn, and
wherein the solder layer is made of a solder material made of AuSn.

5. The semiconductor laser apparatus of claim 1, wherein in the incomplete adherent region, a void is formed between the outermost surface and the solder layer.

6. The semiconductor laser apparatus of claim 1, wherein a part included in the incomplete adherent region of the outermost surface is made of Mo, and
wherein a part included in the complete adherent region of the outermost surface is made of alloy of a material containing Au and a solder material made of AuSn, and
wherein the solder layer is made of a solder material made of AuSn.

7. The semiconductor laser apparatus of claim 1, wherein the incomplete adherent region and the complete adherent region are formed alternately along the longitudinal direction of the semiconductor laser device in an area ranging outward by the predetermined distance on either side from the virtual plane which passes through the center in the width direction of the light-emitting region and which is perpendicular to the width direction.

8. A semiconductor laser device that is adhered to a mount via a solder layer, comprising:
a stripe-shaped light-emitting region; and
an outermost surface which is electrically conductive and to which the solder layer is applied, the outermost surface having an incomplete adherent region and a complete adherent region,
wherein the incomplete adherent region is incompletely adhered to the solder layer, extends in a width direction perpendicular to a longitudinal direction of the light-emitting region and a stacking direction of the semiconductor laser device, the solder layer and the mount, outwardly to either side by a predetermined distance from a virtual plane which passes through a center of the light-emitting region and is perpendicular to the width direction, and the incomplete adherent region has a longitudinal length shorter than that of the light-emitting region, and the complete adherent region is adhered to the solder layer and extends over an area of the outermost surface excluding the incomplete adherent region.
